(19) United States
(12) Patent Application Publication
(10) Pub. No.: US 2026/0005666 A1
(43) Pub. Date: Jan. 1, 2026

(54) RESONATOR ELEMENT

(71) Applicant: SEIKO EPSON CORPORATION, Tokyo (JP)

(72) Inventor: Kazuyuki Nagata, Minowa-machi (JP)

(21) Appl. No.: 19/251,379

(22) Filed: Jun. 26, 2025

(30) Foreign Application Priority Data
Jun. 28, 2024 (JP) 2024-104634

(51) Int. Cl. H03H 9/02

(52) U.S. Cl. CPC H03H 9/02448; H03H 9/02259; H03H 2009/02251; H03H 2009/02291

(57) ABSTRACT

A resonator element includes first to third vibrating arms and weights disposed at respective tip end portions of the first to third vibrating arms. When a weight mass ratio A represented by M1/M2 is plotted on a horizontal axis and an arm width ratio B represented by W1/W2 is plotted on a vertical axis, where M1 is a mass of the weight disposed on the first vibrating arm, M2 is a mass of the weight disposed on each of the second and third vibrating arms, W1 is a width of the first vibrating arm, and W2 is a width of each of the second and third vibrating arms, a point (A, B) is located in a region surrounded by a polygon formed by connecting six points of (A, B)=(2.39, 2), (0.01, 2), (0.23, 1.6), (1.65, 1), (7.15, 1), and (4.02, 1.6) with straight lines.

The present application is based on, and claims priority from JP Application Serial Number 2024-104634, filed Jun. 28, 2024, the disclosure of which is hereby incorporated by reference herein in its entirety.

### BACKGROUND

### 1. Technical Field

The present disclosure relates to a resonator element.

### 2. Related Art

The resonator element described in JP-A-2021-164130 includes a base and three vibrating arms extending from the base in a Y-axis direction. In addition, the three vibrating arms are arranged in an X-axis direction orthogonal to the Y-axis direction and each include a piezoelectric element on the upper surface. When the piezoelectric elements, to which a drive voltage is applied, expand and contract, each vibrating arm vibrates in a Z-axis direction orthogonal to the X-axis and the Y-axis.

Here, the vibrating arms are linearly deformed by the force applied due to the expansion and contraction of the piezoelectric elements. That is, the larger the expansion and contraction of the piezoelectric elements, the larger the amplitude of the vibrating arms. However, when a force of a predetermined level or more is applied, the spring rigidity of the vibrating arms apparently increases, and the vibrating arms are not easily deformed. That is, the linear relationship between the force applied to the vibrating arms and the deformation of the vibrating arms is broken. Such a phenomenon is also referred to as nonlinearity of a spring. When the nonlinearity appears, the vibration frequency of the resonator element varies depending on the magnitude of the drive voltage, which affects the oscillation stability. In JP-A-2021-164130, since such nonlinearity is not taken into consideration, the oscillation stability may be reduced.

### SUMMARY

A resonator element according to the present disclosure includes a base, three vibrating arms extending from the base in a first direction and arranged side by side in a second direction orthogonal to the first direction, and weights disposed at respective tip end portions of the vibrating arms. When a weight mass ratio A represented by M1/M2 is plotted on a horizontal axis and an arm width ratio B represented by W1/W2 is plotted on a vertical axis, where M1 is a mass of the weight disposed on the vibrating arm located at a center of an arrangement of the three vibrating arms, M2 is a mass of the weight disposed on each of the vibrating arms located at both ends of the arrangement, W1 is a width of the vibrating arm located at the center of the arrangement, and W2 is a width of each of the vibrating arms located at both ends of the arrangement, the widths being lengths in the second direction, a point (A, B) is located in a region surrounded by a polygon formed by connecting six points of (A, B)=(2.39, 2), (A, B)=(0.01, 2), (A, B)=(0.23, 1.6), (A, B)=(1.65, 1), (A, B)=(7.15, 1), and (A, B)=(4.02, 1.6) with straight lines.

### BRIEF DESCRIPTION OF THE DRAWINGS

FIG. 1 is a plan view of a MEMS element according to a first embodiment.

FIG. 2 is a sectional view taken along line II-II in FIG. 1.

FIG. 3 is a plan view of a resonator element included in the MEMS element.

FIG. 4 is a sectional view of vibrating arms included in the resonator element.

FIG. 5 is a graph illustrating a relationship between a weight mass ratio A and an arm width ratio B.

FIG. 6 is a graph illustrating a relationship between the arm width ratio B and a Q value.

FIG. 7 is a graph illustrating a relationship between the weight mass ratio A and a frequency difference Δf.

FIG. 8 is a plan view illustrating configurations of weights.

FIG. 9 is a sectional view illustrating configurations of the weights.

FIG. 10 is a plan view illustrating configurations of the weights.

FIG. 11 is a plan view illustrating a resonator element according to a second embodiment.

### DESCRIPTION OF EMBODIMENTS

Hereinafter, a resonator element according to the present disclosure will be described in detail on the basis of embodiments illustrated in the accompanying drawings.

### First Embodiment

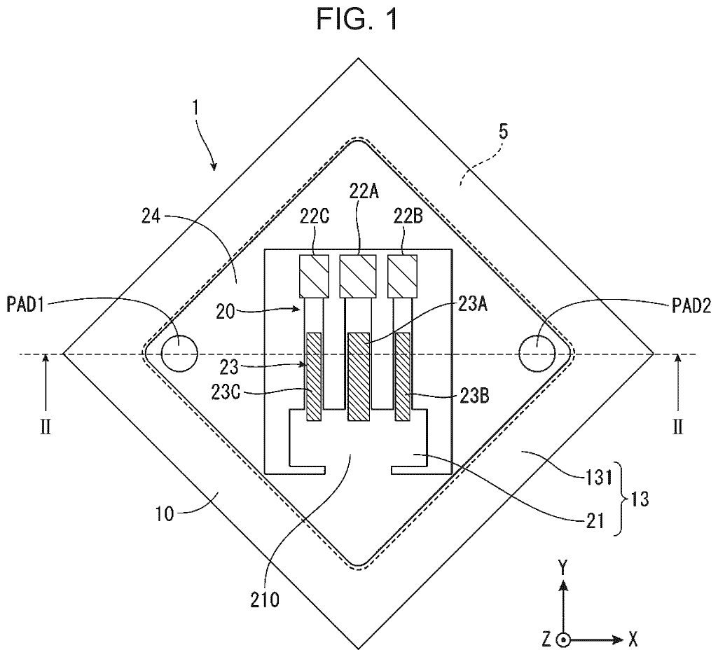

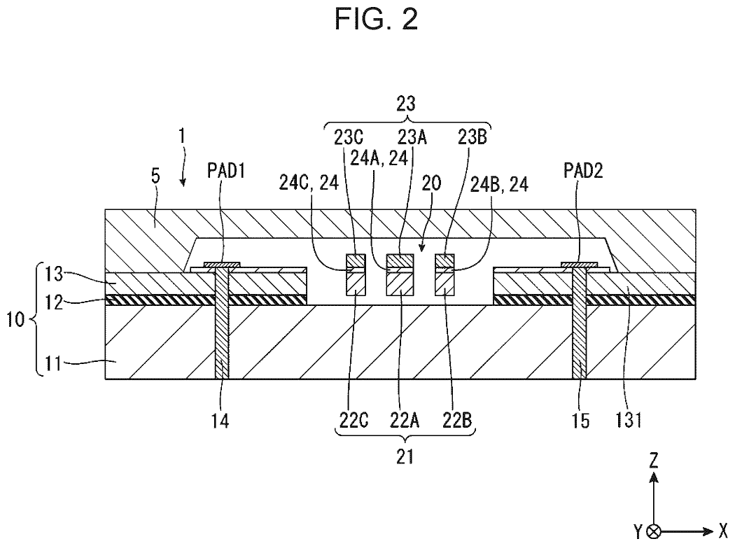

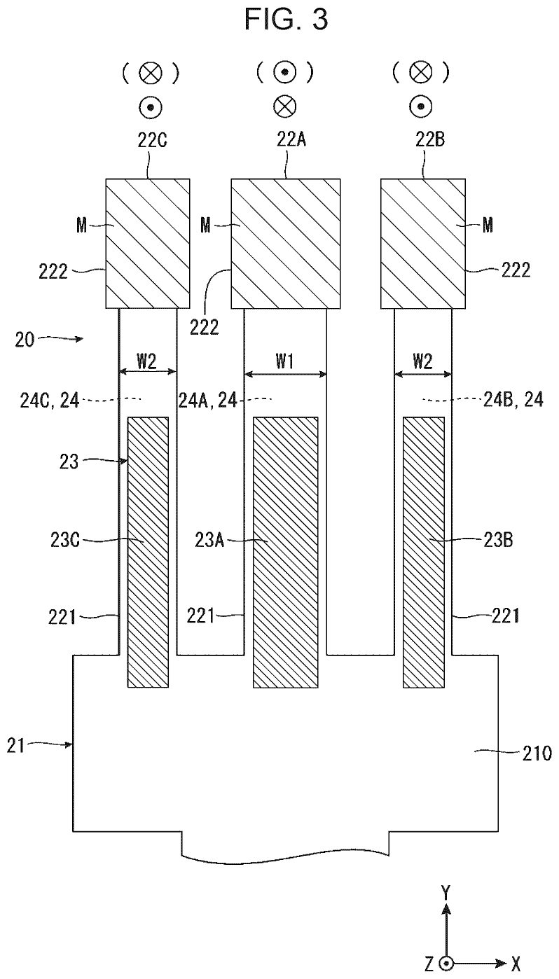

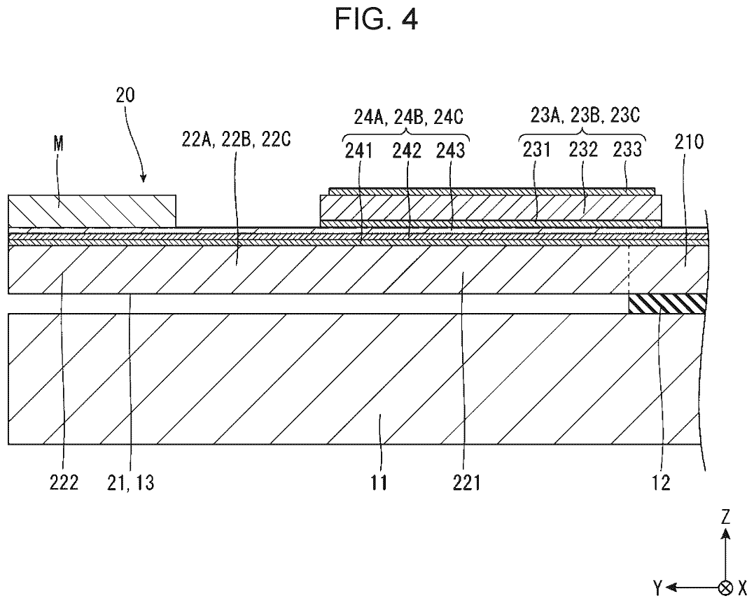

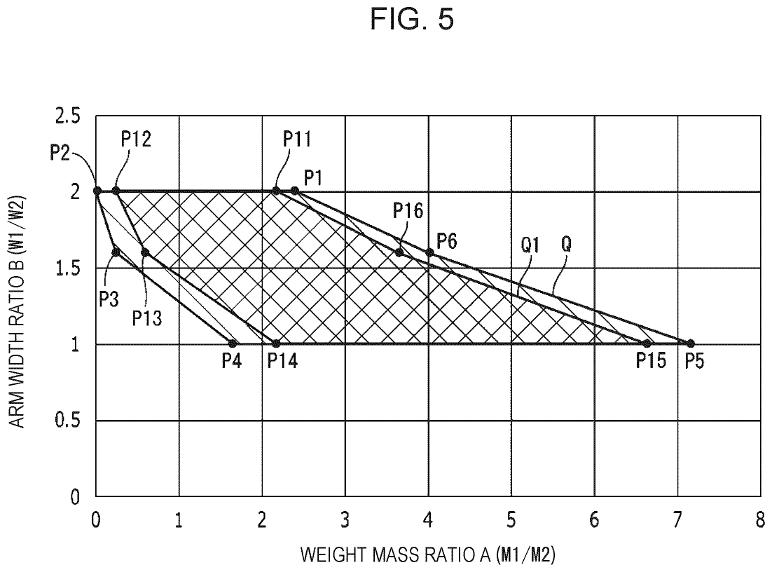

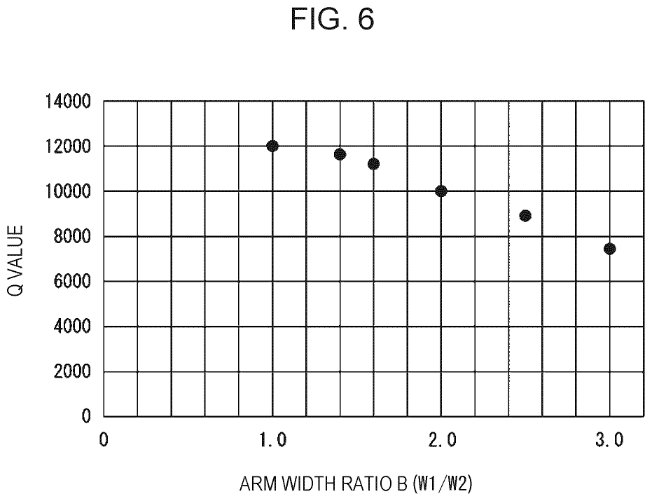

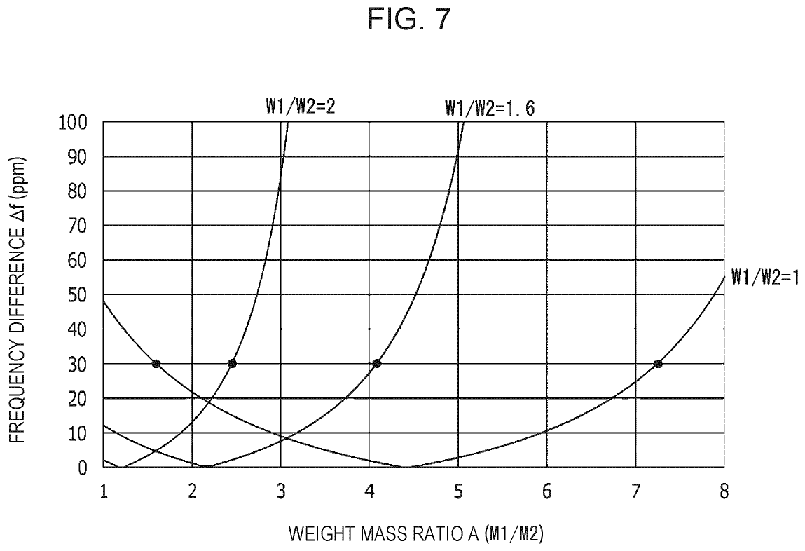

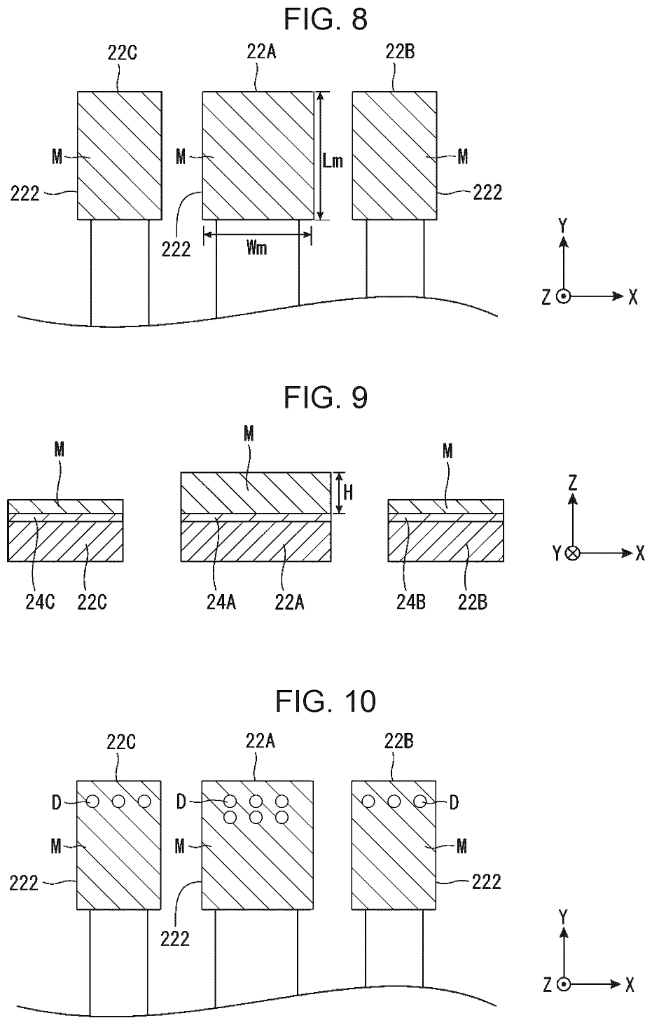

FIG. 1 is a plan view of a MEMS element according to a first embodiment. FIG. 2 is a sectional view taken along line II-II in FIG. 1. FIG. 3 is a plan view of the resonator element included in the MEMS element. FIG. 4 is a sectional view of vibrating arms included in the resonator element. FIG. 5 is a graph illustrating a relationship between a weight mass ratio A and an arm width ratio B. FIG. 6 is a graph illustrating a relationship between the arm width ratio B and a Q value. FIG. 7 is a graph illustrating a relationship between the weight mass ratio A and a frequency difference Δf. FIG. 8 is a plan view illustrating configurations of weights. FIG. 9 is a sectional view illustrating configurations of the weights. FIG. 10 is a plan view illustrating configurations of the weights.

For convenience of description, an X-axis, a Y-axis, and a Z-axis orthogonal to each other are illustrated in the drawings except FIGS. 5 to 7. In addition, a direction along the X-axis is also referred to as an X-axis direction, a direction along the Y-axis is also referred to as a Y-axis direction, and a direction along the Z-axis is also referred to as a Z-axis direction. The X-axis direction corresponds to a “second direction”, the Y-axis direction corresponds to a “first direction”, and the Z-axis direction corresponds to a “third direction”. The arrow side of each axis is also referred to as a “plus side”, and the opposite side is also referred to as a “minus side”. The plus side in the Z-axis direction is also referred to as “up”, and the minus side is also referred to as “down”.

As illustrated in FIGS. 1 and 2, a MEMS element 1 includes a silicon-on-insulator (SOI) substrate 10 on which a resonator element 20 is formed, and a lid 5 that hermetically seals the resonator element 20 between the lid 5 and the SOI substrate 10. The lid 5 is made of single-crystal silicon or the like and has a recessed portion opened on the lower surface. The lower surface of the lid 5 is bonded to the upper surface of the SOI substrate 10. As illustrated in FIG. 2, the SOI substrate 10 is a multilayer substrate in which a silicon layer 11 as a handle layer, a buried oxide (BOX) layer 12, and a surface silicon layer 13 as a device layer are stacked in this order from the lower side. For example, the silicon layer 11 and the surface silicon layer 13 are each made of single crystal silicon, and the BOX layer 12 is made of a silicon oxide (SiO₂) layer.

In addition, as illustrated in FIG. 1, a vibrating substrate 21 included in the resonator element 20 and a frame-shaped frame 131 surrounding the periphery of the vibrating substrate 21 are formed in the surface silicon layer 13. Moreover, a pair of electrode pads PAD1 and PAD2 is disposed on the upper surface of the frame 131. In addition, as illustrated in FIG. 2, through electrodes 14 and 15 that extend through the SOI substrate 10 in a thickness direction are formed at positions overlapping with the electrode pads PAD1 and PAD2, respectively. The through electrode 14 is electrically connected to the electrode pad PAD1, and the through electrode 15 is electrically connected to the electrode pad PAD2. As a result, the electrode pads PAD1 and PAD2 are extended to the outside from the lower surface of the MEMS element 1. Therefore, electrical connection with an external device such as an oscillation circuit is facilitated.

In addition, the resonator element 20 includes the vibrating substrate 21 formed on the surface silicon layer 13. That is, the vibrating substrate 21 is formed of a silicon substrate. Since the vibrating substrate 21 is formed of a silicon substrate, the vibrating substrate 21 can be formed using a silicon wafer process, and thus the vibrating substrate 21 can be easily processed, and the vibrating substrate 21 can be formed with high processing accuracy.

The vibrating substrate 21 has a plate shape and includes an upper surface and a lower surface which are in a front-back relationship. As illustrated in FIG. 3, the vibrating substrate 21 includes a base 210 and three vibrating arms 22A, 22B, and 22C extending from the base 210. As illustrated in FIG. 4, the base 210 is supported by the silicon layer 11 and the BOX layer 12 located below, whereas the vibrating arms 22A, 22B, and 22C are separated from the BOX layer 12. Therefore, the vibrating arms 22A, 22B, and 22C are cantilever beams cantilevered by the base 210 at base end portions. The entire vibrating substrate 21 is formed so as to have the same thickness as the surface silicon layer 13.

As illustrated in FIG. 3, the vibrating arms 22A, 22B, and 22C extend from the base 210 toward the plus side in the Y-axis direction and are arranged side by side at equal intervals in the X-axis direction. Specifically, the vibrating arm 22A is located at the center of the arrangement, the vibrating arm 22B is located on the plus side of the vibrating arm 22A in the X-axis direction, and the vibrating arm 22C is located on the minus side of the vibrating arm 22A in the X-axis direction. In other words, the vibrating arm 22A is located between the vibrating arms 22B and 22C. Each of the vibrating arms 22A, 22B, and 22C includes an arm portion 221 extending from the base 210 to the plus side in the Y-axis direction, and a wide portion 222 disposed on the tip end side of the arm portion 221 and wider than the arm portion 221. Hereinafter, for convenience of description, the length of each of the vibrating arms 22A, 22B, and 22C in the Y-axis direction is referred to as a “length”, and the length in the X-axis direction is referred to as a “width”.

Each arm portion 221 has a straight shape, and the width thereof is constant in the Y-axis direction. The width of the wide portions 222 is larger than the width of the arm portions 221. Each wide portion 222 has a straight shape, and the width thereof is constant in the Y-axis direction. According to such a configuration, the mass of the tip end portion of each of the vibrating arms 22A, 22B, and 22C increases due to a mass effect of the wide portions 222. Therefore, when the resonance frequency of the resonator element 20 is the same, it is possible to shorten the total lengths of the vibrating arms 22A, 22B, and 22C compared to a case where the wide portions 222 are not provided, and it is possible to reduce the size of the resonator element 20. Alternatively, when the total lengths of the vibrating arms 22A, 22B, and 22C are the same, the resonance frequency of the resonator element 20 can be lowered compared to the case where the wide portions 222 are not provided. However, the wide portions 222 may be omitted from each of the vibrating arms 22A, 22B, and 22C.

In addition, the resonator element 20 has a thin film-shaped weight M disposed on the tip end portion of each of the vibrating arms 22A, 22B, and 22C, that is, on the upper surface of each of the wide portions 222 in the present embodiment. By disposing the weights M, the mass of the wide portions 222 is further increased, and the mass effect described above becomes more remarkable. The constituent material of the weights M is not particularly limited, but the weights M preferably contain at least one of aluminum (Al), titanium (Ti), chromium (Cr), gold (Au), silver (Ag), copper (Cu), and polysilicon (Si), for example. The term “aluminum (Al)” described above includes aluminum and aluminum compounds such as aluminum oxide and aluminum nitride. The same applies to other materials. Although not illustrated, the weights M of the present embodiment have a configuration in which a surface layer of gold (Au) is stacked on a base layer of titanium (Ti). With these materials, the weights M having a high specific gravity can be easily formed. However, the weights M may be omitted.

In addition, as illustrated in FIGS. 2 and 3, the resonator element 20 includes a temperature characteristic adjuster 24 that adjusts the frequency-temperature characteristics of the resonance frequency. The temperature characteristic adjuster 24 includes a temperature characteristic adjustment film 24A disposed on the upper surface of the vibrating arm 22A, a temperature characteristic adjustment film 24B disposed on the upper surface of the vibrating arm 22B, and a temperature characteristic adjustment film 24C disposed on the upper surface of the vibrating arm 22C.

As illustrated in FIG. 4, the temperature characteristic adjustment films 24A, 24B, and 24C are disposed to extend over the base 210 and the arm portions 221. In other words, the temperature characteristic adjustment films 24A, 24B, and 24C are disposed so as to overlap with the boundary portions between the base 210 and the arm portions 221. The temperature characteristic adjustment films 24A, 24B, and 24C described above are formed of a stacked body of a first layer 241, which is a silicon oxide (SiO₂) layer, and a second layer 242, which is a zirconium oxide (ZrO₂) layer, and the stacked body is covered with a polysilicon layer 243 serving as a covering layer. Silicon, which is a constituent material of the vibrating substrate 21, has frequency-temperature characteristics in which the resonance frequency decreases as the temperature increases. On the other hand, silicon oxide (SiO₂) and zirconium oxide (ZrO₂) have frequency-temperature characteristics in which the resonance frequency increases as the temperature increases. Therefore, these frequency-temperature characteristics cancel each other, and the frequency-temperature characteristics of the resonance frequency of a composite body composed of the vibrating arms 22A, 22B, and 22C and the temperature characteristic adjustment films 24A, 24B, and 24C can be made close to flat. For example, a change amount of approximately ±3,000 ppm of the resonance frequency of the vibrating substrate 21 in a temperature range of −25° C. to +75° C. can be flattened to approximately +200 ppm to approximately +500 ppm by disposing the temperature characteristic adjuster 24.

The configuration of the temperature characteristic adjustment films 24A, 24B, and 24C is not particularly limited, and the temperature characteristic adjustment films 24A, 24B, and 24C may be composed of only one of the first layer 241 and the second layer 242. Moreover, another layer may be included in addition to the first and second layers 241 and 242. In addition, the temperature characteristic adjuster 24 may be omitted.

As illustrated in FIG. 3, the resonator element 20 includes a drive unit 23 that causes the vibrating arms 22A, 22B, and 22C to flexurally vibrate in the Z-axis direction. The drive unit 23 includes a piezoelectric element 23A disposed above the upper surface of the vibrating arm 22A so as to be superimposed on the temperature characteristic adjustment film 24A, a piezoelectric element 23B disposed above the upper surface of the vibrating arm 22B so as to be superimposed on the temperature characteristic adjustment film 24B, and a piezoelectric element 23C disposed above the upper surface of the vibrating arm 22C so as to be superimposed on the temperature characteristic adjustment film 24C. The piezoelectric elements 23A, 23B, and 23C are shorter than the arm portions 221 and are disposed in regions occupying approximately half of the vibrating arms 22A, 22B, and 22C on the base end side. In addition, the piezoelectric elements 23A, 23B, and 23C are disposed to extend over the base 210 and the arm portions 221. Each of the piezoelectric elements 23A, 23B, and 23C expands and contracts in the Y-axis direction by application of a drive voltage. When the piezoelectric elements 23A, 23B, and 23C expand and contract in the Y-axis direction, the vibrating arms 22A, 22B, and 22C flexurally vibrate in the Z-axis direction. In order to balance the vibration, in the resonator element 20, at least the vibrating arms 22B and 22C located at both ends of the arrangement have the same configuration (shape and size), and the vibrating arm 22A at the center has a configuration (shape and size) different from the vibrating arms 22B and 22C as necessary. This will be described in detail later.

The piezoelectric elements 23A, 23B, and 23C have the same configuration and, as illustrated in FIG. 4, each include a lower electrode 231, a piezoelectric layer 232 disposed on the upper surface of the lower electrode 231, and an upper electrode 233 disposed on the upper surface of the piezoelectric layer 232. The constituent material of each portion of the piezoelectric elements 23A, 23B, and 23C is not particularly limited. For example, the piezoelectric layer 232 is formed of aluminum nitride (AlN) or the like, and the lower electrode 231 and the upper electrodes 233 are formed of titanium nitride (TiN) or the like. However, the configuration of the piezoelectric elements 23A, 23B, and 23C is not particularly limited, and another layer may be interposed between the respective layers.

As illustrated in FIG. 3, the piezoelectric elements 23A, 23B, and 23C described above are wired such that the vibrating arms 22A, 22B, and 22C adjacent to each other flexurally vibrate in opposite phases to each other. In other words, the piezoelectric elements 23A, 23B, and 23C are wired such that a first state, in which the vibrating arms 22B and 22C are flexurally deformed upward and the vibrating arm 22A is flexurally deformed downward, and a second state, in which the vibrating arms 22B and 22C are flexurally deformed downward and the vibrating arm 22A is flexurally deformed upward, are alternately repeated. Specifically, the lower electrodes 231 of the piezoelectric elements 23B and 23C and the upper electrode 233 of the piezoelectric element 23A are electrically connected to the electrode pad PAD1 via wiring (not illustrated), and the upper electrodes 233 of the piezoelectric elements 23B and 23C and the lower electrode 231 of the piezoelectric element 23A are electrically connected to the electrode pad PAD2 via wiring (not illustrated).

In this manner, by causing the adjacent vibrating arms 22A, 22B, and 22C to flexurally vibrate in opposite phases to each other, the vibrations of the vibrating arms 22A, 22B, and 22C are at least partially canceled, and thus it is possible to effectively suppress the vibration leakage of the resonator element 20. The flexural vibrations of the vibrating arms 22A, 22B, and 22C are greatly excited at the resonance frequency, and the impedance is minimized. As a result, by connecting the MEMS element 1 to an oscillation circuit, an oscillator that oscillates at an oscillation frequency determined by the resonance frequency is obtained.

The entire configuration of the resonator element 20 has been described above. Next, dimensions of the resonator element 20 will be described in detail. FIG. 5 is a graph in which a weight mass ratio A represented by M1/M2 is plotted on a horizontal axis and an arm width ratio B represented by W1/W2 is plotted on a vertical axis, where M1 is the mass of the weight M disposed on the vibrating arm 22A located at the center of the arrangement of the three vibrating arms 22A, 22B, and 22C, M2 is the mass of the weight M disposed on each of the vibrating arms 22B and 22C located at both ends of the arrangement, W1 is the width of the arm portion 221 of the vibrating arm 22A, and W2 is the width of the arm portion 221 of each of the vibrating arms 22B and 22C.

In the graph, when a region Q surrounded by a polygon formed by connecting six points of a point P1 (A, B)=(2.39, 2), a point P2 (A, B)=(0.01, 2), a point P3 (A, B)=(0.23, 1.6), a point P4 (A, B)=(1.65, 1), a point P5 (A, B)=(7.15, 1), and a point P6 (A, B)=(4.02, 1.6) with straight lines is set, the weight mass ratio A and the arm width ratio B are set such that the point (A, B) of the resonator element 20 is located in the region Q. According to such a configuration, nonlinearity of a spring is less likely to appear, and it is possible to reduce the change in the frequency of the resonator element 20 due to the drive voltage applied to the piezoelectric elements 23A, 23B, and 23C. Preferably, a frequency difference Δf between a frequency f1 when the drive voltage is 10 mV and a frequency f2 when the drive voltage is 100 mV can be suppressed to 30 ppm or less. In addition, the Q value of the resonator element 20 can be set to 10,000 or more. Therefore, the resonator element 20 having high oscillation stability and frequency characteristics is obtained.

Hereinafter, the reason why the above-described effect is obtained will be described. In the resonator element 20, the vibrating arm 22A at the center and the vibrating arms 22B and 22C at both ends vibrate in opposite phases. When there is a difference between a total mass Mb of the vibrating arms 22B and 22C vibrating in the same phase (the mass of the vibrating arm 22B+the mass of the vibrating arm 22C) and a mass Ma of the vibrating arm 22A vibrating in the opposite phase to the vibrating arms 22B and 22C, the lighter of the vibrating arms vibrates more largely than the heavier of the vibrating arms. For example, in the case of Ma<Mb, the vibrating arm 22A vibrates more largely than the vibrating arms 22B and 22C. In this manner, when only one or two vibrating arms of the vibrating arms 22A, 22B, and 22C vibrate largely, the one or two vibrating arms reach a nonlinear region earlier than other vibrating arms, and thus the nonlinearity described above appears early. That is, the nonlinearity appears at a lower drive voltage. For this reason, in order to make the nonlinearity less likely to appear, it is preferable to, for example, make the width W1 of the vibrating arm 22A larger than the width W2 of each of the vibrating arms 22B and 22C to make the difference between the mass Ma and the total mass Mb sufficiently small, and make the amplitudes of the vibrating arms 22A, 22B, and 22C substantially equal to each other. From this viewpoint, approximately 1≤W1/W2≤3 is preferable.

However, as illustrated in FIG. 6, as W1/W2, which is the ratio between the widths W1 and W2, increases, the Q value of the resonator element 20 decreases. That is, when W1/W2 is excessively increased in order to make the nonlinearity less likely to appear, the Q value of the resonator element 20 decreases, and the oscillation stability of the resonator element 20 decreases. Therefore, W1/W2 in the resonator element 20 satisfies 1≤W1/W2≤2. According to such a configuration, it is possible to make the nonlinearity less likely to appear while keeping the Q value sufficiently high. As described above, the optimum value of the arm width ratio B is obtained.

Next, the relationship between the weight mass ratio A and the frequency difference Δf was obtained for W1/W2=1, which is the lower limit value, W1/W2=2, which is the upper limit value, and W1/W2=1.6, which is near the center value, within the range of the 1≤W1/W2≤2. The results are illustrated in the graph of FIG. 7. In the graph, when W1/W2=1, the weight mass ratio A at which the frequency difference Δf=30 ppm is 1.65 and 7.15. When W1/W2=1.6, the weight mass ratio A at which the frequency difference Δf=30 ppm is 0.23 and 4.02. When W1/W2=2, the weight mass ratio A at which the frequency difference Δf=30 ppm is 0.01 and 2.39.

On the basis of the above-described results, the six points of the point P1 (A, B)=(2.39, 2), the point P2 (A, B)=(0.01, 2), the point P3 (A, B)=(0.23, 1.6), the point P4 (A, B)=(1.65, 1), the point P5 (A, B)=(7.15, 1), and the point P6 (A, B)=(4.02, 1.6) are plotted on a graph with the arm width ratio B on the vertical axis and the weight mass ratio A on the horizontal axis, and the region Q surrounded by a polygon formed by connecting these six points with straight lines is set, as illustrated in FIG. 5. Therefore, if the point (A, B) is located in the region Q, the frequency difference Δf can be suppressed to 30 ppm or less, and the Q value can be maintained at 10,000 or more. As described above, by determining the weight mass ratio A and the arm width ratio B such that the point (A, B) is located in the region Q, the resonator element 20 having high oscillation stability and frequency characteristics is obtained.

Moreover, in the graph illustrated in FIG. 7, when W1/W2=1, the weight mass ratio A at which the frequency difference Δf=20 ppm is 2.17 and 6.63. When W1/W2=1.6, the weight mass ratio A at which the frequency difference Δf=20 ppm is 0.6 and 3.66. When W1/W2=2, the weight mass ratio A at which the frequency difference Δf=20 ppm is 0.24 and 2.17. Therefore, as illustrated in FIG. 5, six points of a point P11 (A, B)=(2.17, 2), a point P12 (A, B)=(0.24, 2), a point P13 (A, B)=(0.6, 1.6), a point P14 (A, B)=(2.17, 1), a point P15 (A, B)=(6.63, 1), and a point P16 (A, B)=(3.66, 1.6) are plotted, and a region Q1 surrounded by a polygon formed by connecting these six points with straight lines is set. Therefore, when the point (A, B) is located in the region Q1, the frequency difference Δf can be suppressed to 20 ppm or less, and the Q value can be maintained at 10,000 or more. For this reason, it is preferable to further determine the weight mass ratio A and the arm width ratio B so that the point (A, B) is located within the region Q1. As a result, the resonator element 20 having higher oscillation stability and frequency characteristics is obtained.

In the region Q, the weight mass ratio A>1 or the weight mass ratio A<1 is more preferable. That is, the weight mass ratio A≠1 is preferable. According to such a configuration, a difference ΔM between the total mass Mb of the vibrating arms 22B and 22C and the mass Ma of the vibrating arm 22A generated at the determined arm width ratio B can be further reduced by using the weight mass ratio A. That is, if Ma<Mb is satisfied when the arm width ratio B is determined, the difference ΔM can be further reduced by setting the weight mass ratio A>1. On the other hand, if Ma>Mb is satisfied when the arm width ratio B is determined, the difference ΔM can be further reduced by setting the weight mass ratio A<1. On the other hand, when the weight mass ratio A=1, the above-described effect is not obtained. Therefore, by setting the weight mass ratio A>1 or the weight mass ratio A<1, it is possible to suppress the difference in the amplitudes of the vibrating arms 22A, 22B, and 22C to make it smaller, and it is possible to make the nonlinearity less likely to appear. As a result, the drive voltage can be set to be higher.

Next, a method of achieving the determined weight mass ratio A will be described. In the present embodiment, as illustrated in FIG. 8, the determined weight mass ratio A may be achieved by making at least one of a length Lm, that is, the length of the weight M in the Y-axis direction, and a width Wm, that is, the length of the weight M in the X-axis direction, different between the vibrating arm 22A located at the center of the arrangement and each of the vibrating arms 22B and 22C located at both ends of the arrangement. In other words, the determined weight mass ratio A may be achieved by making the area of the weight M as seen in plan view in the Z-axis direction different between the vibrating arm 22A and each of the vibrating arms 22B and 22C. In the illustrated example, both the length Lm and the width Wm are different. According to such a method, the determined weight mass ratio A can be achieved with a simple configuration.

However, the present disclosure is not limited thereto, and for example, the determined weight mass ratio A can also be achieved by making a thickness H, that is, the length of the weight M in the Z-axis direction different between the vibrating arm 22A located at the center of the arrangement and each of the vibrating arms 22B and 22C located at both ends of the arrangement as illustrated in FIG. 9. According to such a method, the determined weight mass ratio A can also be achieved with a simple configuration.

In addition, for example, in the resonator element 20, a process of removing a portion of the weight M by irradiating the weight M with a laser is performed in order to adjust the resonance frequency of the resonator element 20. When such a process is performed, the determined weight mass ratio A may be achieved by making the total area of laser processing marks D for frequency adjustment formed in the weight M different between the vibrating arm 22A located at the center of the arrangement and each of the vibrating arms 22B and 22C located at both ends of the arrangement as illustrated in FIG. 10. According to such a method, the determined weight mass ratio A can also be achieved with a simple configuration. Needless to say, the above-described three methods can be appropriately combined.

The MEMS element 1 has been described above. As described above, the resonator element 20 included in the MEMS element 1 includes the base 210, the three vibrating arms 22A, 22B, and 22C extending from the base 210 in the Y-axis direction as the first direction and arranged side by side in the X-axis direction as the second direction orthogonal to the Y-axis direction, and the weights M disposed at the respective tip end portions of the vibrating arms 22A, 22B, and 22C. In addition, when the weight mass ratio A represented by M1/M2 is plotted on the horizontal axis and the arm width ratio B represented by W1/W2 is plotted on the vertical axis, where M1 is the mass of the weight M disposed on the vibrating arm 22A located at the center of the arrangement, M2 is the mass of the weight M disposed on each of the vibrating arms 22B and 22C located at both ends of the arrangement, W1 is the width of the vibrating arm 22A located at the center of the arrangement, and W2 is the width of each of the vibrating arms 22B and 22C located at both ends of the arrangement, the widths being lengths in the X-axis direction, the point (A, B) is located in the region Q surrounded by a polygon formed by connecting six points of (A, B)=(2.39, 2), (A, B)=(0.01, 2), (A, B)=(0.23, 1.6), (A, B)=(1.65, 1), (A, B)=(7.15, 1), and (A, B)=(4.02, 1.6) with straight lines. According to such a configuration, the resonator element 20 having high oscillation stability and frequency characteristics is obtained.

In addition, as described above, the point (A, B) is located in the region Q1 surrounded by a polygon formed by connecting six points of (A, B)=(2.17, 2), (A, B)=(0.24, 2), (A, B)=(0.6, 1.6), (A, B)=(2.17, 1), (A, B)=(6.63, 1), and (A, B)=(3.66, 1.6) with straight lines. According to such a configuration, the resonator element 20 having higher oscillation stability and frequency characteristics is obtained.

In addition, as described above, the weight mass ratio A>1 is satisfied. With such a configuration, it is possible to suppress the difference in the amplitudes of the vibrating arms 22A, 22B, and 22C to make it smaller, and it is possible to make the nonlinearity less likely to appear. As a result, the drive voltage can be set to be higher.

In addition, as described above, the weight mass ratio A<1 is satisfied. With such a configuration, it is possible to suppress the difference in the amplitudes of the vibrating arms 22A, 22B, and 22C to make it smaller, and it is possible to make the nonlinearity less likely to appear. As a result, the drive voltage can be set to be higher.

In addition, as described above, the thickness H, which is the length in the Z-axis direction, is different between the weight M disposed on the vibrating arm 22A located at the center of the arrangement and the weight M disposed on each of the vibrating arms 22B and 22C located at both ends of the arrangement. According to such a configuration, the determined weight mass ratio A can be achieved by a simple method.

In addition, as described above, in the resonator element 20, at least one of the length Lm in the Y-axis direction and the width Wm, which is the length in the X-axis direction, is different between the weight M disposed on the vibrating arm 22A located at the center of the arrangement and the weight M disposed on each of the vibrating arms 22B and 22C located at both ends of the arrangement. According to such a configuration, the determined weight mass ratio A can be achieved by a simple method.

In addition, as described above, in the resonator element 20, the total area of the laser processing marks D formed for frequency adjustment is different between the weight M disposed on the vibrating arm 22A located at the center of the arrangement and the weight M disposed on each of the vibrating arms 22B and 22C disposed at both ends of the arrangement. According to such a configuration, the determined weight mass ratio A can be achieved by a simple method.

In addition, as described above, each of the three vibrating arms 22A, 22B, and 22C includes the arm portion 221 extending from the base 210 and the wide portion 222 located on the tip end side of the arm portion 221 and wider than the arm portion 221, and each of the weights M is disposed in the wide portion 222. According to such a configuration, the mass of the tip end portion of each of the vibrating arms 22A, 22B, and 22C increases due to the mass effect of the wide portions 222. Therefore, when the resonance frequency of the resonator element 20 is the same, it is possible to shorten the total lengths of the vibrating arms 22A, 22B, and 22C compared to the case where the wide portions 222 are not provided, and it is possible to reduce the size of the resonator element 20. Alternatively, when the total lengths of the vibrating arms 22A, 22B, and 22C are the same, the resonance frequency of the resonator element 20 can be lowered compared to the case where the wide portions 222 are not provided.

In addition, as described above, the resonator element 20 includes the temperature characteristic adjuster 24 that is disposed on each of the vibrating arms 22A, 22B, and 22C and adjusts the frequency-temperature characteristics. According to such a configuration, it is possible to improve the frequency-temperature characteristics of the vibrating substrate 21.

### Second Embodiment

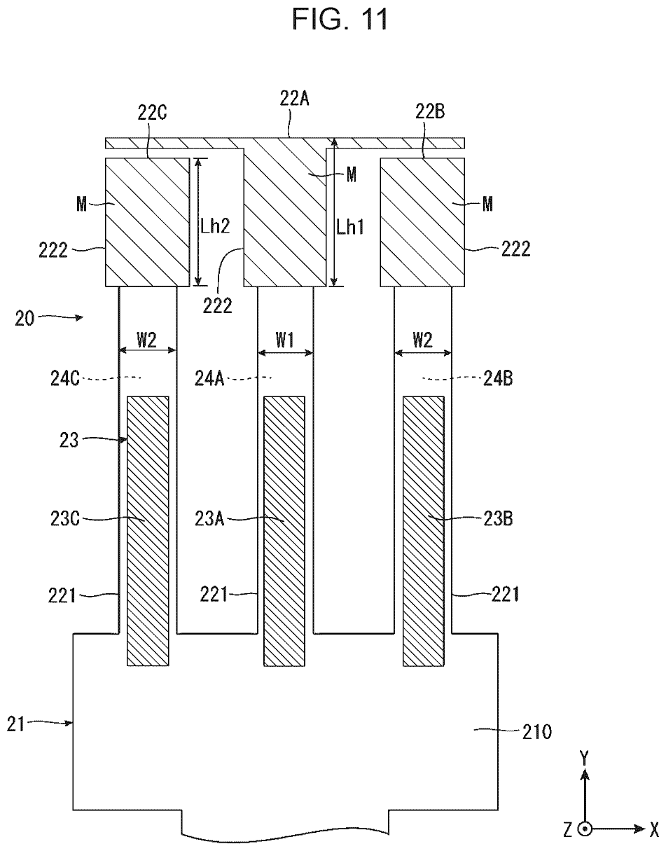

FIG. 11 is a plan view illustrating a resonator element according to a second embodiment.

The MEMS element 1 according to the present embodiment is the same as the MEMS element 1 of the first embodiment described above except that the configuration of the vibrating arm 22A is different. Therefore, in the following description, the MEMS element 1 of the present embodiment will be described focusing on the differences from the first embodiment described above, and similar items will be omitted in description. In addition, in each drawing of the present embodiment, the same reference numerals are given to the same components as those in the embodiment described above.

As illustrated in FIG. 11, in the resonator element 20 of the present embodiment, the width W1 of the vibrating arm 22A is equal to the width W2 of each of the vibrating arms 22B and 22C. That is, W1=W2 and the arm width ratio B=1 are satisfied. In addition, when the vibrating arm 22A is compared with the vibrating arms 22B and 22C, the lengths of the arm portions 221 are equal to each other, but the wide portion 222 of the vibrating arm 22A is longer than those of the vibrating arms 22B and 22C. Therefore, the length Lh1 of the wide portion 222 of the vibrating arm 22A is greater than the length Lh2 of the wide portion 222 of each of the vibrating arms 22B and 22C. According to such a configuration, the mass of the vibrating arm 22A is larger than the masses of the vibrating arms 22B and 22C, and by adjusting the length Lh1 of the wide portion 222 of the vibrating arm 22A, it is possible to suppress the difference ΔM between the total mass Mb of the vibrating arms 22B and 22C and the mass Ma of the vibrating arm 22A to make it small. Therefore, it is possible to further suppress the difference in the amplitudes of the vibrating arms 22A, 22B, and 22C to make it smaller, and it is possible to make nonlinearity less likely to appear.

In particular, in the present embodiment, the tip end portion of the weight M of the vibrating arm 22A protrudes to both sides in the X-axis direction. As a result, it is possible to increase the mass of the weight M without excessively increasing the length Lh1 of the weight M of the vibrating arm 22A. However, the configuration of the weight M is not particularly limited.

In the second embodiment described above, too, the same advantageous effect as that of the first embodiment described above can be achieved.

Although the resonator element according to the present disclosure has been described above on the basis of the embodiments illustrated in the drawings, the present disclosure is not limited thereto. The configuration of each portion can be replaced with any configuration having the same function. In addition, any other configurations may be added to the present disclosure. For example, in the embodiments described above, the vibrating substrate 21 is made of silicon, but the present disclosure is not limited thereto. For example, the vibrating substrate 21 may be made of quartz crystal, or may be made of a piezoelectric material other than quartz crystal.

What is claimed is:

1. A resonator element comprising:
a base;
three vibrating arms extending from the base in a first direction and arranged side by side in a second direction orthogonal to the first direction; and
weights disposed at respective tip end portions of the vibrating arms, wherein
when a weight mass ratio A represented by M1/M2 is plotted on a horizontal axis and an arm width ratio B represented by W1/W2 is plotted on a vertical axis, where M1 is a mass of the weight disposed on the vibrating arm located at a center of an arrangement of the three vibrating arms, M2 is a mass of the weight disposed on each of the vibrating arms located at both ends of the arrangement, W1 is a width of the vibrating arm located at the center of the arrangement, and W2 is a width of each of the vibrating arms located at both ends of the arrangement, the widths being lengths in the second direction,
a point (A, B) is located in a region surrounded by a polygon formed by connecting six points of (A, B)=(2.39, 2), (A, B)=(0.01, 2), (A, B)=(0.23, 1.6), (A, B)=(1.65, 1), (A, B)=(7.15, 1), and (A, B)=(4.02, 1.6) with straight lines.

2. The resonator element according to claim 1, wherein
the point (A, B) is located in a region surrounded by a polygon formed by connecting six points of (A, B)=(2.17, 2), (A, B)=(0.24, 2), (A, B)=(0.6, 1.6), (A, B)=(2.17, 1), (A, B)=(6.63, 1), and (A, B)=(3.66, 1.6) with straight lines.

3. The resonator element according to claim 1, wherein A>1.

4. The resonator element according to claim 1, wherein A<1.

5. The resonator element according to claim 1, wherein
when a direction orthogonal to the first direction and the second direction is a third direction,
a length in the third direction is different between the weight disposed on the vibrating arm located at the center of the arrangement and the weight disposed on each of the vibrating arms located at both ends of the arrangement.

6. The resonator element according to claim 1, wherein
at least one of a length in the first direction and a length in the second direction is different between the weight disposed on the vibrating arm located at the center of the arrangement and the weight disposed on each of the vibrating arms located at both ends of the arrangement.

7. The resonator element according to claim 1, wherein
a total area of a laser processing mark formed for frequency adjustment is different between the weight disposed on the vibrating arm located at the center of the arrangement and the weight disposed on each of the vibrating arms located at both ends of the arrangement.

8. The resonator element according to claim 1, wherein
each of the three vibrating arms includes
an arm portion extending from the base, and
a wide portion located on a tip end side of the arm portion and wider than the arm portion, and
each of the weights is disposed on the wide portion.

9. The resonator element according to claim 1, further comprising
a temperature characteristic adjuster that is disposed on each of the vibrating arms and adjusts a frequency-temperature characteristic.

10. A resonator element comprising:
a base;
a first vibrating arm extending from the base in a first direction;
a second vibrating arm and a third vibrating arm extending from the base in a first direction and disposed on both sides of the first vibrating arm in a second direction orthogonal to the first direction; and
weights disposed at respective tip end portions of the first to third vibrating arms, wherein
when a weight mass ratio A represented by M1/M2 is plotted on a horizontal axis and an arm width ratio B represented by W1/W2 is plotted on a vertical axis, where M1 is a mass of the weight disposed on the first vibrating arm, M2 is a mass of the weight disposed on each of the second vibrating arm and the third vibrating arm, W1 is a width of the first vibrating arm, and W2 is a width of each of the second vibrating arm and the third vibrating arm, the widths being lengths in the second direction,
a point (A, B) is located in a region surrounded by a polygon formed by connecting six points of (A, B)=(2.39, 2), (A, B)=(0.01, 2), (A, B)=(0.23, 1.6), (A, B)=(1.65, 1), (A, B)=(7.15, 1), and (A, B)=(4.02, 1.6) with straight lines.
